(19) United States
(12) Patent Application Publication
(10) Pub. No.: US 2013/0049074 A1
(43) Pub. Date: Feb. 28, 2013

(54) METHODS FOR FORMING CONNECTIONS TO A MEMORY ARRAY AND PERIPHERY

(71) Applicants: Shyam Surthi, Boise, ID (US); Hung-Ming Tsai, Boise, ID (US)

(72) Inventors: Shyam Surthi, Boise, ID (US); Hung-Ming Tsai, Boise, ID (US)

(73) Assignee: Micron Technology, Inc., Boise, ID (US)

(21) Appl. No.: 13/216,164

(22) Filed: Aug. 23, 2011

(51) Int. Cl. H01L 23/52; H01L 21/768

(52) U.S. Cl. 257/208; 438/648; 257/E21.575; 257/E23.141

(57) ABSTRACT

Methods are disclosed for forming connections to a memory array and a periphery of the array. The methods include forming stacks of conductive materials on the array and the periphery and forming a step between the periphery stack and the array stack. The step is removed during subsequent processing, and connections are formed from the conductive materials remaining on the array and the periphery. In some embodiments, the step is removed before any photolithographic processes.

### BACKGROUND

1. Field of Invention

Embodiments of the invention relate generally to electronic devices and, more specifically, in certain embodiments, to methods of forming connections to a memory array.

2. Description of Related Art

Electronic devices are generally employed in numerous configurations to provide a variety of functions. Processing speeds, system flexibility, and size constraints are typically considered by design engineers tasked with developing electronic devices such as computer systems and system components. Such electronic devices generally include memory devices which may be used to store programs and data and which may be accessible to other system components such as processors or peripheral devices. Such memory devices may include volatile and non-volatile memory devices.

Many types of memory devices have data cells. Typically, the data cells each include a data element (e.g., a memory element, an imaging element, or other device configured to output data, such as various kinds of sensors) and, in some instances, an access device, such as a transistor or diode. Generally, the access device controls access to the data element, and the data element outputs signals indicative of stored or sensed data.

Often the data elements are arranged in an array, e.g., generally in rows and columns. Data cells within the array are accessed, e.g., written to or read from, through circuitry near the periphery of the array and through connections to the access devices of the data cells. For instance, sense amplifiers or other sensing circuitry are often positioned adjacent arrays of data cells for reading data. Similarly, address decoders, e.g., row and column address decoders, are often disposed adjacent the array for addressing particular data cells or groups of data cells. Additionally conductive lines, such as access lines and digit lines, may be connected to the access devices.

Devices in the array often are structured differently from structures in the periphery. Array transistors may be formed from materials that are different from the materials used to form transistors in the periphery, and the dimensions, e.g., thickness, of materials in these devices may be different. In some devices, differences between the array and periphery are accommodated with multiple lithography steps. For instance, a first photolithography tool may pattern a first material in the array, and a second, different photolithography tool, may pattern a second, different material in the periphery. In this way, different design tradeoffs, e.g., size versus signal quality, may be made between the array devices and the periphery devices. Additionally, processing of the periphery may add additional steps to a manufacturing process.

### BRIEF DESCRIPTION OF DRAWINGS

FIG. 1 is a perspective view of a portion of a memory array in accordance with an embodiment of the present invention;

FIG. 2 is a front view of a portion of a memory array and the periphery in accordance with an embodiment of the present invention;

FIGS. 3-30 illustrate a process for forming connections to the array and periphery of FIG. 2 in accordance with an embodiment of the present invention; and

FIGS. 31-49 illustrate a process for forming connections to the array and periphery of FIG. 2 in accordance with another embodiment of the present invention.

### DETAILED DESCRIPTION

As discussed in further detail below, embodiments of the present invention include a manufacturing process integrating formation of a conductive plate and a peripheral access line gate. The process includes integrating part of the peripheral access line gate and conductive plate stack deposition into one step and using a stop layer from the conductive plate stack to define the stack height of the peripheral gate. The stack height differential between the conductive gate stack and the peripheral gate stack is maintained for some portions of the process and then eliminated through subsequent processing steps.

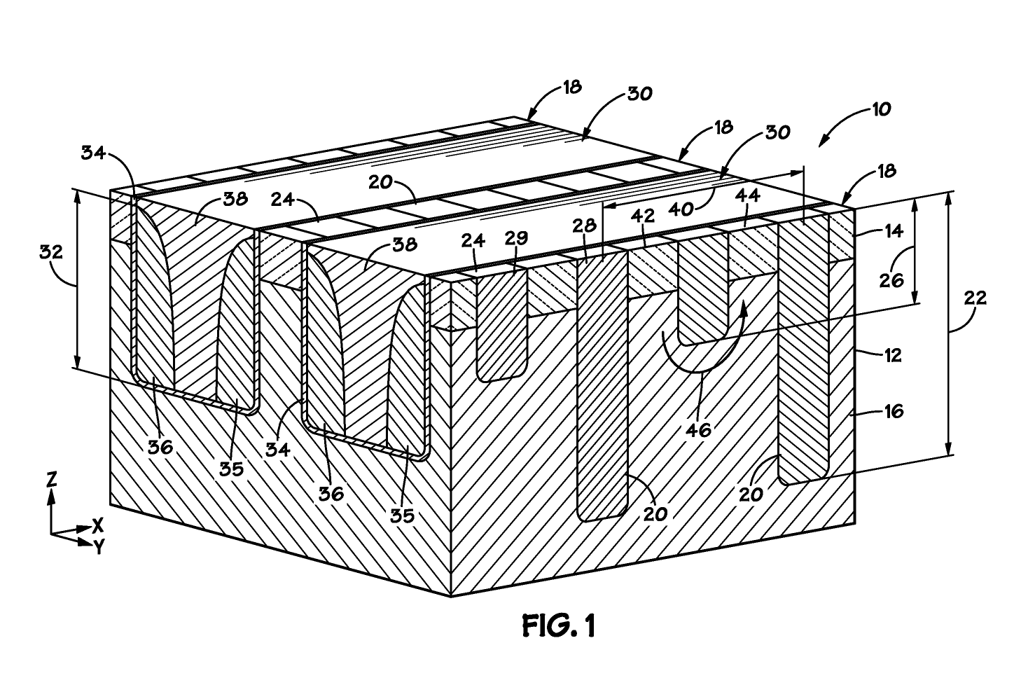

Turning now to the figures, FIG. 1 illustrates a portion of a memory array 10 formed in a substrate 12 in accordance with an embodiment of the present invention. The substrate 12 may include semiconductive materials such as single-crystal or poly-crystalline silicon, gallium arsenide, indium phosphide, or other materials with semiconductor properties. Alternately, or additionally, the substrate 12 may include a non-semiconductor body on which an electronic device may be constructed, e.g., a body such as a plastic or ceramic work surface. The term “substrate” encompasses these structures in a variety of stages of manufacture, including an unprocessed whole wafer, a partially-processed whole wafer, a fully-processed whole wafer, a portion of a diced wafer, or a portion of a diced wafer in a packaged electronic device.

The substrate 12 may include an upper doped region 14 and a lower doped region 16. The depth of the upper doped region 14 may be generally uniform over a substantial area of the substrate 12, and the upper doped region 14 may be doped differently from the lower doped region 16. For example, the upper-doped region 14 may include an n+ material and the lower-doped region 16 may include a p− material or vise versa.

As illustrated by FIG. 1, a plurality of fins 18 may be formed in the substrate 12. As used herein, the term “fin” refers to a tall, thin, semiconductor member extending from a substrate and generally having a length greater than the width and the depth of the fin. Each fin 18 may include a plurality of column isolation trenches 20 formed at a depth 22 and intra-device isolation trenches 24 formed at a depth 26 disposed along the length of each fin 18. The intra-device trenches 24 may have a depth 26 that is both less than the depth 22 of the column isolation trenches 20 and greater than the depth of the upper doped region 14. The column isolation trenches 20 may be filled partially or entirely with a dielectric 28 and the intra-device trenches 24 may be filled with a dielectric 29.

Adjacent fins 18 may be separated by row trenches 30. The row trenches 30 may be formed at a depth 32 that is greater than the depth of the intra-device trenches 24 and less than a depth of the column isolation trenches 20. A gate dielectric 34 may be formed in the row trenches 30 on the sidewalls of the fins 18. The gate dielectric 34 is a relatively thin layer that may be deposited, grown, or otherwise formed, and it may substantially or entirely cover the exposed portions of the upper doped region 112 and the lower doped region 114. The gate dielectric 34 may include a variety of dielectric materials, such as oxide (e.g., silicon dioxide), oxynitride, or high-dielectric constant materials like hafnium dioxide, zirconium dioxide, and titanium dioxide.

Gates 35 and 36 may be formed in the row trenches 30 on the gate dielectric 34 and on the sidewalls of the fins 18. The gates 35 and 36 may connect to one another, e.g., by wrapping around the ends (not shown) of the fins 18, or they may be electrically independent. The gates 35 and 36 may partially or substantially entirely overlap the upper doped region 14. In other embodiments, the gates 35 and 36 may underlap the upper doped region 14. A dielectric 38 may be formed in the row trenches 30, such as through deposition and planarization on the array 10. The dielectric 38 may include an oxide formed with TEOS CVD or other appropriate materials.

Each of the fins 18 may include a plurality of transistors 40. The transistors 40 on a given fin 18 may be isolated from one another by the dielectric 28. Each of the transistors 40 may be selected by one or both of the gates 35 and 36 disposed on either side of the fins 18. The illustrated transistors 40 may be referred to as multi-gate transistors or dual-gate transistors. Other embodiments may include transistors with more than two gates or fewer than two gates. The transistor 40 may include a source 42 and a drain 44 formed from the upper doped region 14. In operation, the transistor 40 may establish a conductive channel 46 extending between the source 42 and drain 44, such as in response to electric fields emanating from the gates 35 and 36. Such a device may be referred to as a “cross-hair cell” as each side of a fin is adjacent to an access line (e.g., gates 35 and/or 36) that connects (i.e., forms a cross-point or cross-hair) with an access device (e.g., the transistors 40 of fins 18).

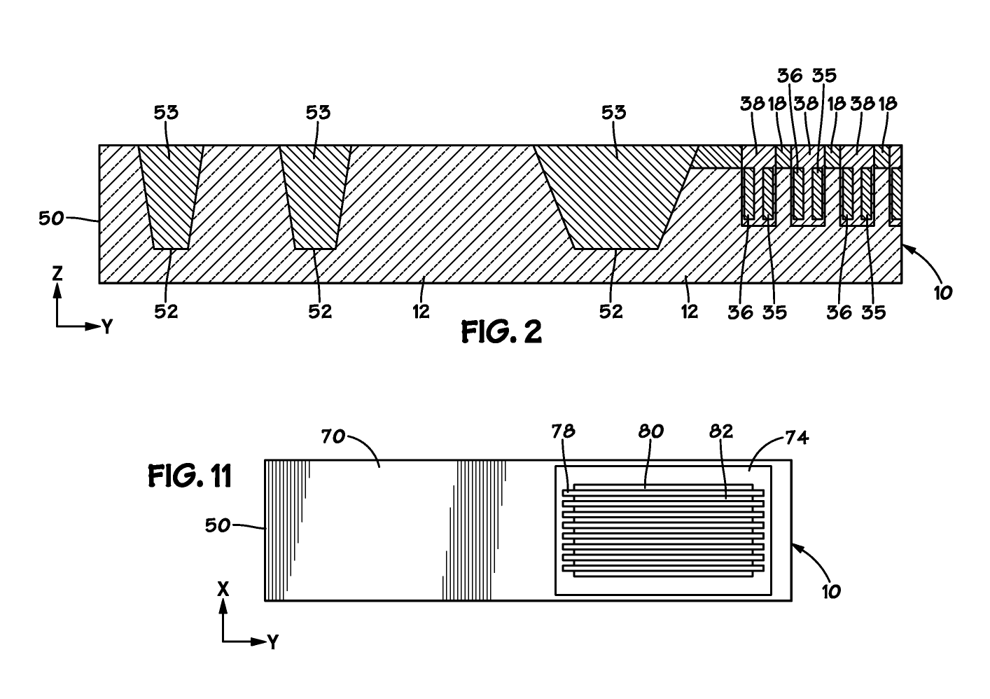

FIG. 2 is a side view of the array portion 10 and a periphery 50 formed in the substrate 12 illustrating, for example, fins 18 and gates 35 and 36. The periphery 50 may generally surround the array 10 or be disposed near a portion of the array 10, e.g., near one or more sides of the array 10. At the stage illustrated by FIG. 2, the periphery 50 may include precursor structures for a variety of devices, such as sense amplifiers, address decoders, and drivers. In some embodiments, the periphery 50 may be doped differently from the array 10. The periphery 50 may include isolation trenches 52 that may isolate subsequently-formed transistors in the periphery 50 and from the array 10. The isolation trenches 52 may be patterned, etched, and filled (such as with a dielectric 53) generally simultaneously with the column isolation trenches 20 (illustrated in FIG. 1), or they may be formed partially or substantially entirely separately.

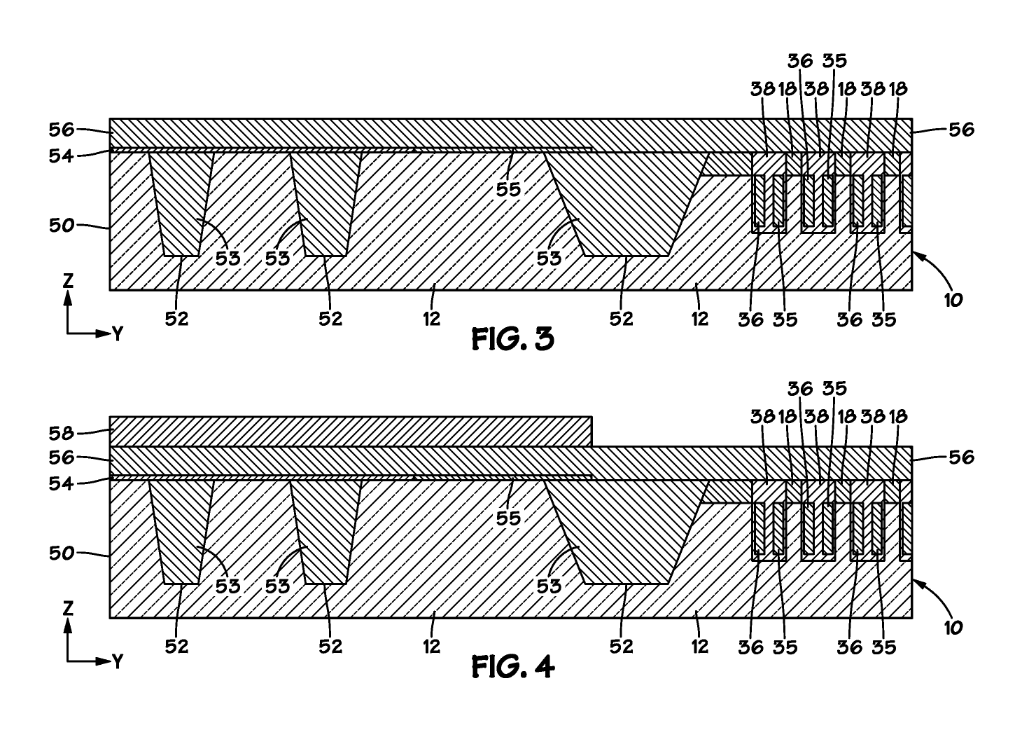

FIGS. 3-30 depict an example of a process for forming conductive components (e.g., conductive plates, connections to such plates, transistors, cells, and access lines, etc.) on the array 10 and periphery 50. Initially, as shown in FIG. 3, gate oxides 54 and 55 may be formed on the periphery 50. The gate oxides 54 and 55 may be formed on different regions of the periphery 50, such as on a portion of or all of the isolation trenches 52. The oxides 54 and 55 may be formed on a portion of or substantially all of the periphery 50. In some embodiments, the gate oxides 54 and 55 may be formed from the same material and processes or may be formed from different materials and/or through different processes. For example, in one embodiment the gate oxide 54 may be a “thin” oxide and the gate oxide 55 may be a “thick” oxide. Further, the gate oxides 54 and 55 may be formed simultaneously or independently. In some embodiments, a nitride (e.g., silicon nitride, etc.) may be formed on the array 10. The nitride may protect the gates 35 and 36 from oxidation during formation of the gate oxides 54 and 55.

Next, a polysilicon 56 may be formed on the gate oxides 54 and 55. As shown in FIG. 3, the polysilicon 56 may be formed on the periphery 50 and on the array 10. In some embodiments, the polysilicon 56 may have a thickness of about 500 Å. In other embodiments, the polysilicon 56 may have a thickness of less than or greater than about 500 Å.

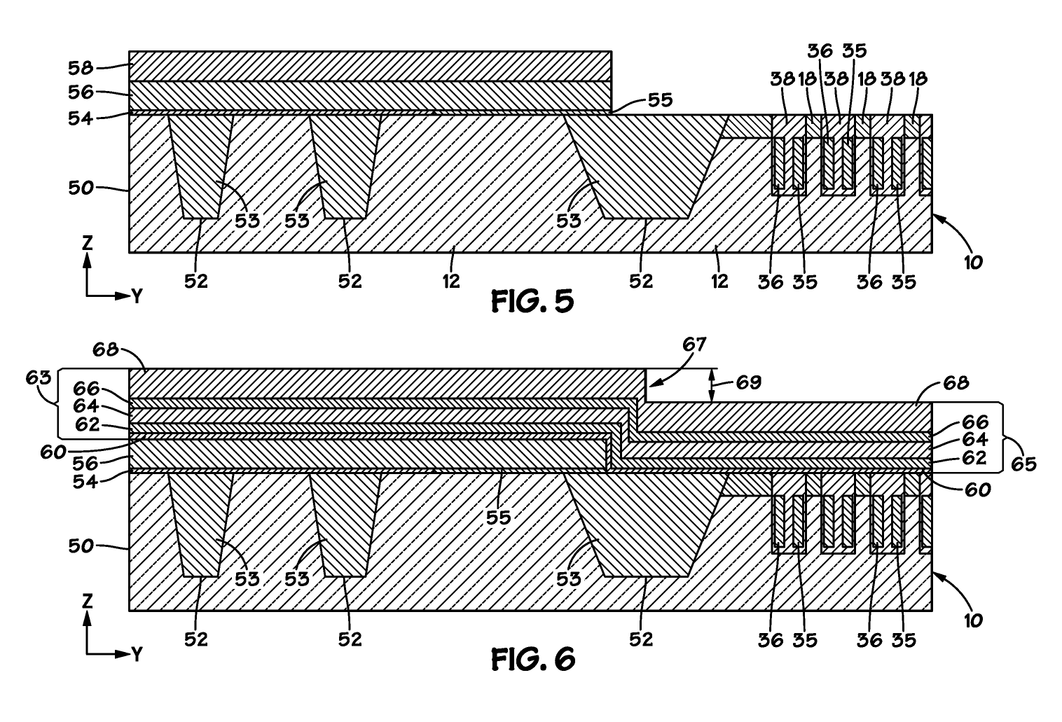

As illustrated in FIG. 4, a mask 58 (e.g., photoresist mask) may be patterned on the periphery 50 and formed on the polysilicon 56. The mask 58 may be formed on some or substantially all of the periphery 50 and not on any portion of the array 10. Next, as shown in FIG. 5, the periphery 50 and array 10 may be etched, such as by dry etching or other suitable processes, to remove the portion of the polysilicon 56 and the gate oxide 55 on the array 10.

FIG. 6 depicts the formation of a stack of materials on the periphery 50 and the array 10. As shown in FIG. 6, the mask 58 may be removed and a polysilicon 60 may be formed on the periphery 50 and the array 10. As shown in FIG. 6, the polysilicon 60 is formed on the remaining polysilicon 56 on the periphery 50 and directly on the exposed array 10. In one embodiment, the second polysilicon 60 may have a thickness of about 150 Å or less than or greater than about 150 Å. The polysilicon 60 may be formed through rapid thermal processing or any other suitable process or combination thereof.

As further shown in FIG. 6, a first conductive material 62 may be formed on the polysilicon 60. The first conductive material 62 may include metal mode titanium, tungsten nitride, tungsten silicide, or a combination thereof. For example, in one embodiment, the first conductive material 62 may have a thickness of about 200 Å and may include titanium having a thickness of about 65 Å, tungsten nitride having a thickness of about 100 Å, and tungsten silicide having a thickness of about 65 Å. In other embodiments, the first conductive material 62 may be formed at a thickness greater than or less than about 200 Å and may include some or all of the above described materials, each at a suitable thickness. The first conductive material 62 may be formed though a metal sputter process or any other suitable process.

Continuing with FIG. 6, a second conductive material 64 may be formed on the first conductive material 62. In one embodiment, the second conductive material 64 may be tungsten and may have a thickness of about 300 Å or greater than or less than about 300 Å. Next, a third conductive material 66 may be formed on the second conductive material 64. In one embodiment, the third conductive material 66 may be titanium nitride and may have a thickness of about 200 Å or greater than or less than about 200 Å. Finally, a fourth conductive material 68 may be formed on the third conductive material 66. In some embodiments, the fourth conductor 68 may be tungsten and may have a thickness of about 500 Å or greater than or less than about 500 Å. As described below, the fourth conductive material 68 may form a conductive plate on the array 10 while the portion of the fourth conductive material 68 on the periphery 50 is removed during subsequent processing.

As shown in FIG. 6, the stack 63 on the periphery 50 and the stack 65 on the array 10 may form a step 67. The difference in height between the stack 63 on the periphery 50 and the stack 65 on the array 10 may form a stack height (also referred to as “step height) differential 69. In some embodiments, this stack height differential 69 may be about 550 Å.

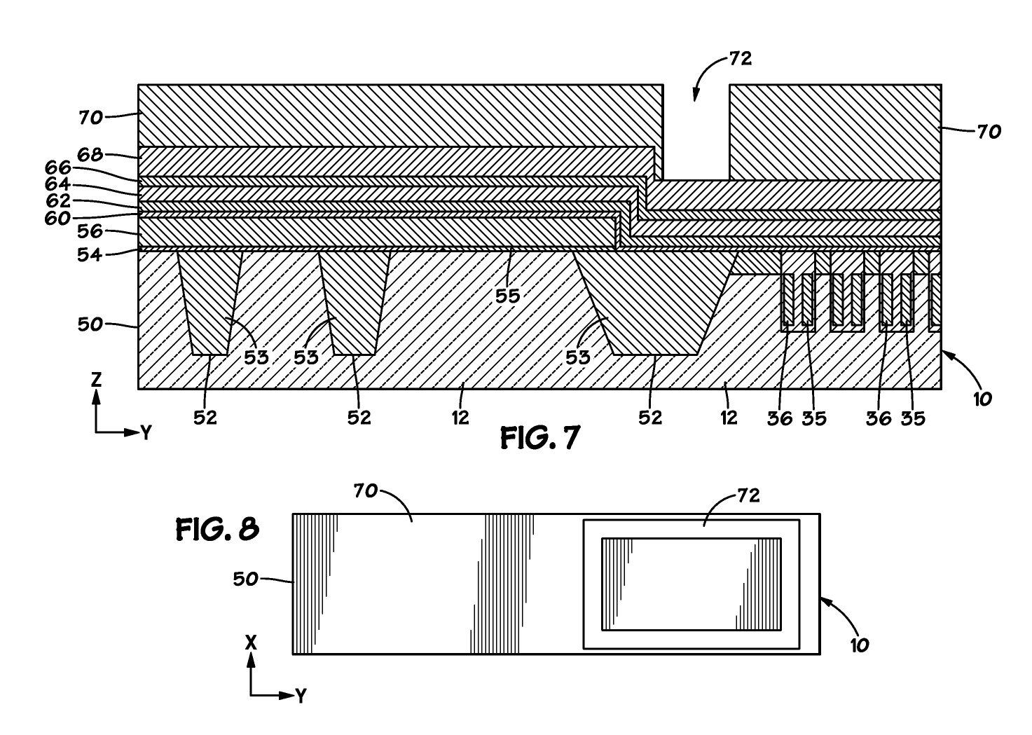

Next, as shown in FIG. 7, a mask 70 (e.g., a photoresist mask) may be patterned on the periphery 50 and on the array 10, such as by suitable photolithographic processes. The mask 70 may define an exposed region 72 around the array 10. FIG. 8 depicts a top view of the periphery 50 and array 10 further illustrating the mask 70 and the exposed region 72. As shown in FIG. 8, the exposed region 72 may form a generally rectangular outline around the array 10, while the periphery 50 and interior of the array 10 are masked by the mask 70.

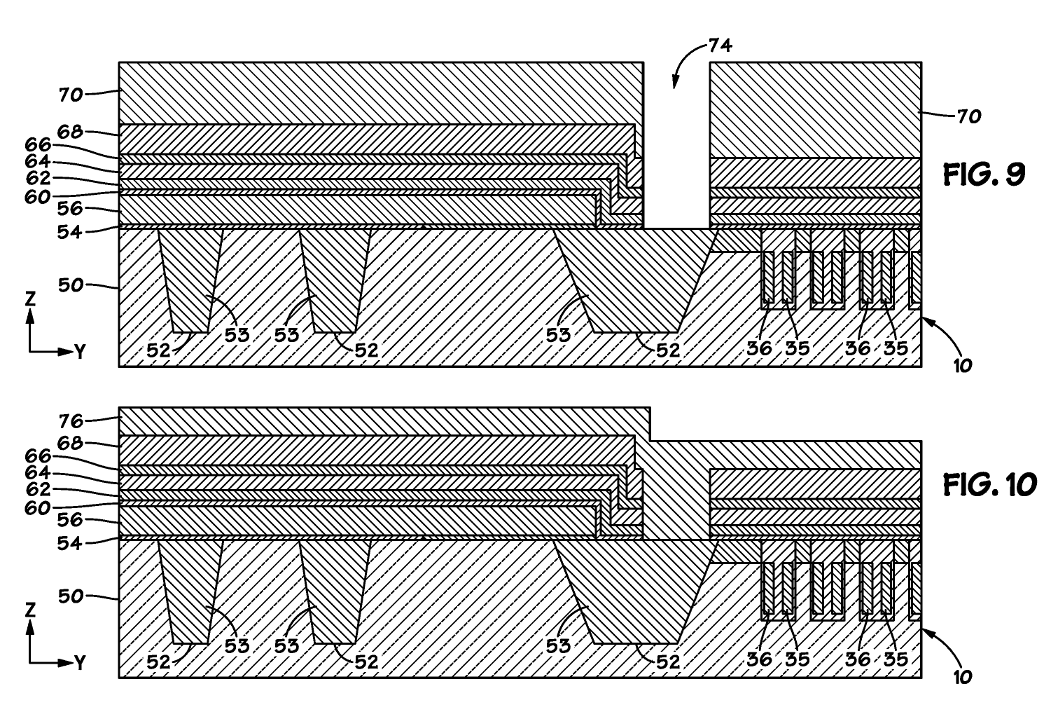

As shown in FIG. 9, the exposed regions 72 of the array 10 may be etched, such as by dry etching, to from a band 74. The band 74 forms a generally rectangular outline around the array 10. As shown in FIG. 9, the band 74 separates the stack 63 on the periphery 50 from the stack 65 on the array 10. Next, as illustrated in FIG. 10, the mask 70 may be removed and a dielectric 76 may be formed on the periphery 50 and the array 10. As shown in FIG. 10, the dielectric 76 may fill the band 74. In some embodiments, the dielectric 76 may be tetraethyl orthosilicate (TEOS) and may have a thickness of about 500 Å or greater than or less than 500 Å.

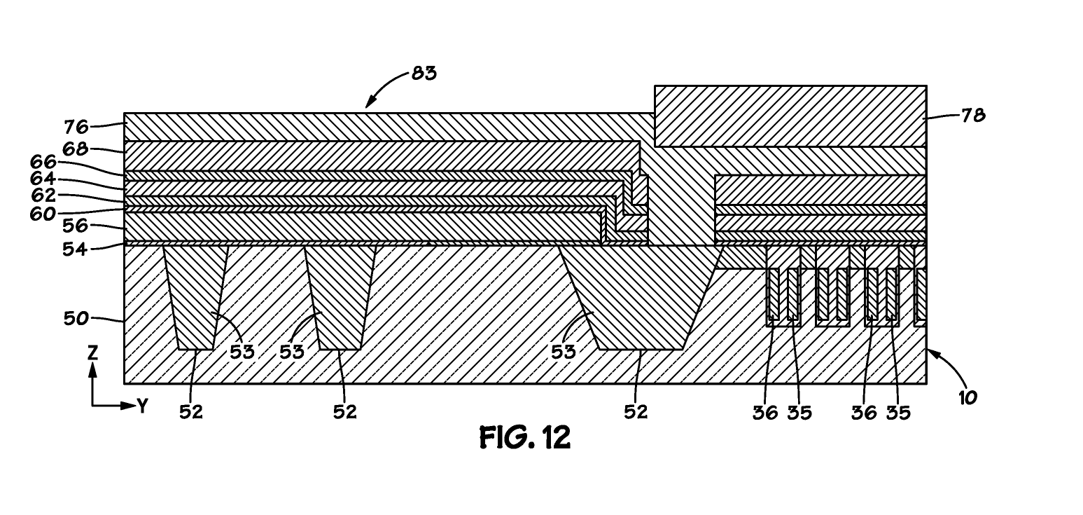

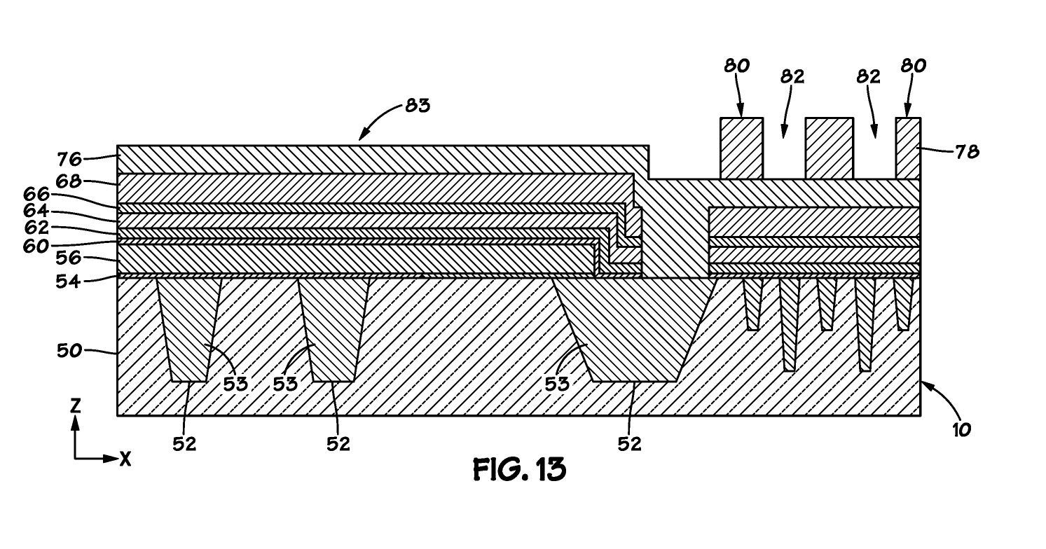

As shown in FIGS. 11-13, a mask 78 may be patterned on the array 10. FIG. 11 is a top view of the periphery 50 and array 10 further illustrating the mask 78. As depicted, the mask 78 may be patterned in rows 80 having exposed regions 82 between the rows 80 and an exposed region 83 over the periphery 50. As shown in FIG. 12, the rows 80 of the mask 78 may be patterned on the array 10 in the Y-direction and may extend up to or slightly beyond the step 67. FIG. 13 is a side view of the periphery 50 and array 10 depicting the mask 78, rows 80, and exposed regions 82. In some embodiments, the rows 80 of the mask 78 may be pitch doubled with respect to the transistors 40

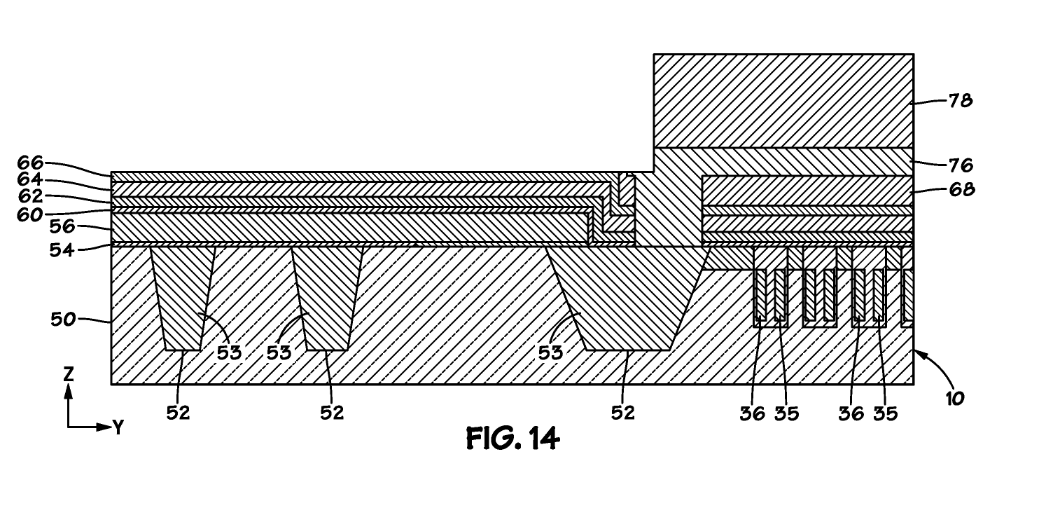

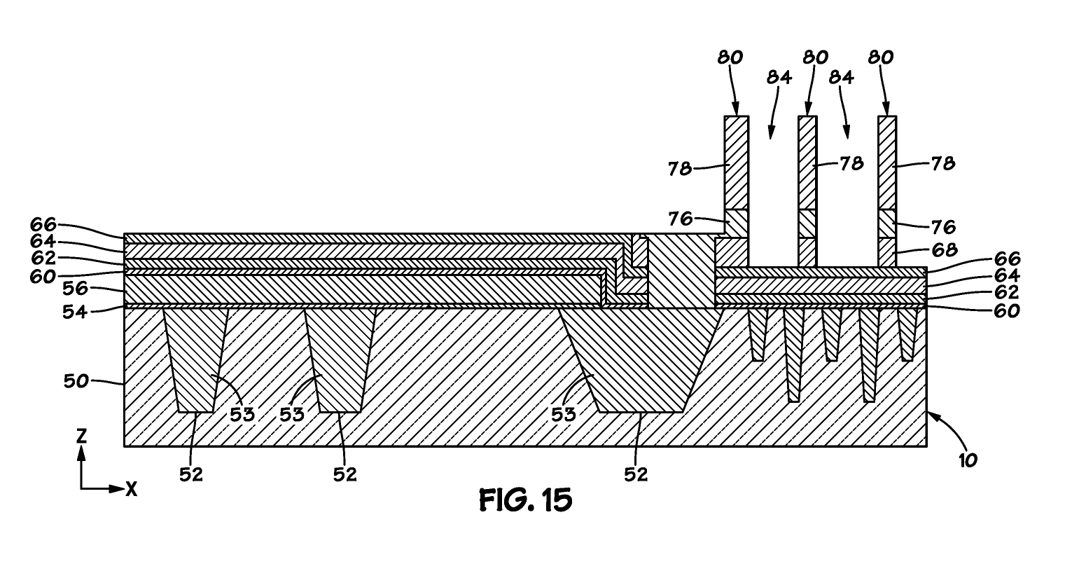

Next, as shown in the front and side views depicted in FIGS. 14 and 15, the exposed regions 82 and 83 may be etched. As shown in FIG. 15, the exposed regions 82 of the mask 78 may be etched to form recesses 84 in the array 10 and between the rows 80. In some embodiments, the etch may use the third conductive material 66 as a stop layer, removing the materials formed on the third conductive material 66. For example, the recesses 84 in the array 10 may be etched up to the third conductive material 66, removing the fourth conductive material 68 and the dielectric 76 in the exposed regions 82. Similarly, the periphery 50 may be etched to remove the materials formed on the third conductive material 66, removing the dielectric 76, and the fourth conductive material 68 on the periphery 50.

As shown in FIG. 15, the fourth conductive material 68 is removed from the periphery 50 but remains on the array 10 in the rows 80. Thus, the formation of the fourth conductive material 68 on the array 10 may be done concurrently with formation of this material on the periphery 50 in a single process step, with later removal of the fourth conductive material 68 illustrated in FIG. 15. Additionally, as also shown in FIG. 5, the step 67 may be removed during the etch, thus eliminating the step height 69.

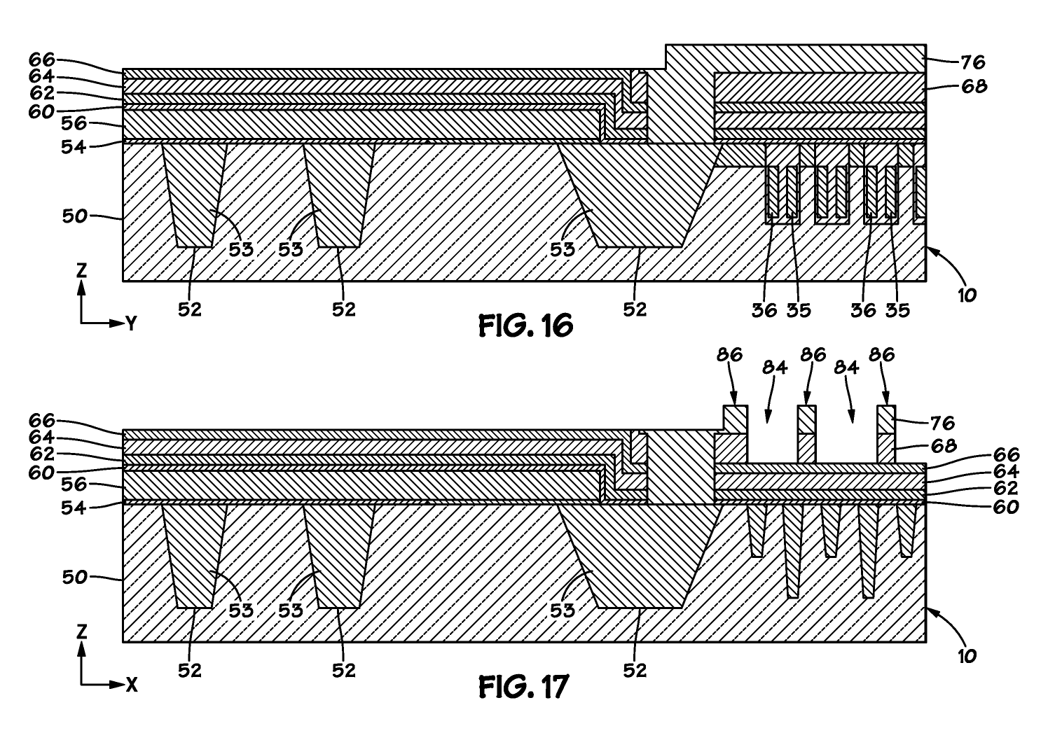

Next, as illustrated in the front and side views depicted in FIGS. 16 and 17 respectively, the mask 78 may be removed, such as by carbon dioxide stripping or other suitable process, leaving rows 86 on the array 10. The rows 86 may be formed from the dielectric 76 and the fourth conductive material 68. As stated above, the rows 86 may be separated by the recesses 84.

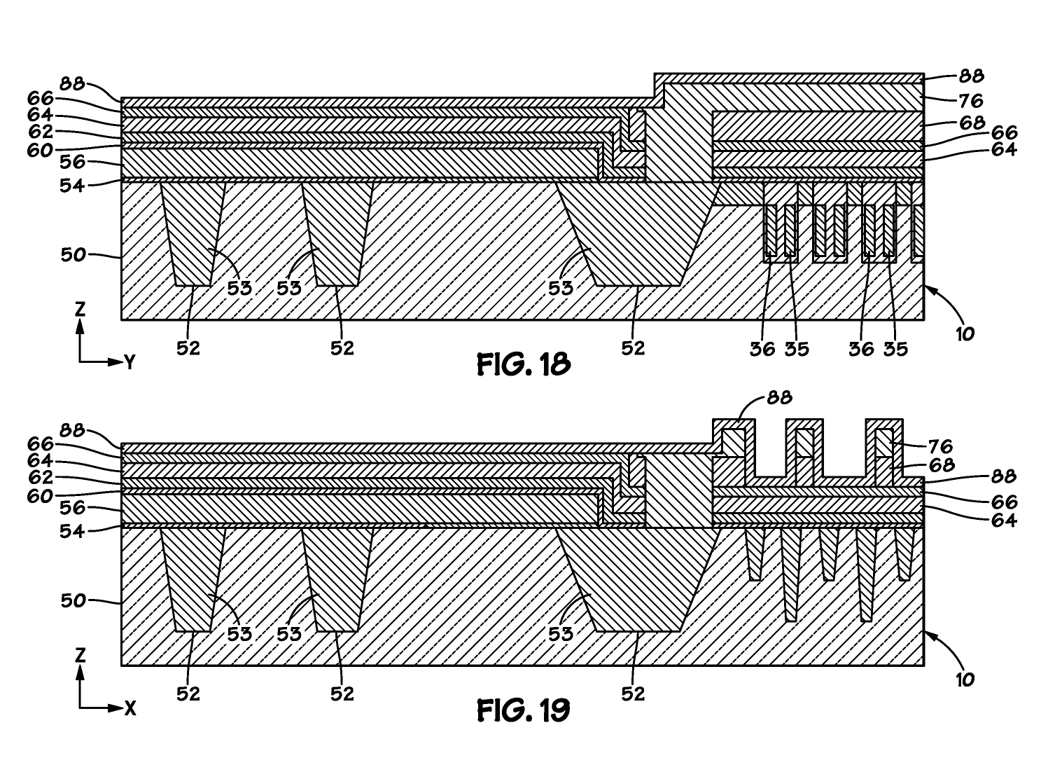

After removal of the mask 78, a polysilicon 88 may be formed on the periphery 50 and the array 10, as shown in the front and side views depicted in FIGS. 18 and 19 respectively. The polysilicon 88 may be formed on the third conductive material 66 on the periphery 50 and on the rows 86 and recesses 84 of the array 10. In some embodiments, the polysilicon 88 may have a thickness of about 150 Å or greater than or less than 150 Å. After formation of the polysilicon 88, the periphery 50 and array 10 may be subjected to ion implantation, such as boron difluoride (BF₂) implantation.

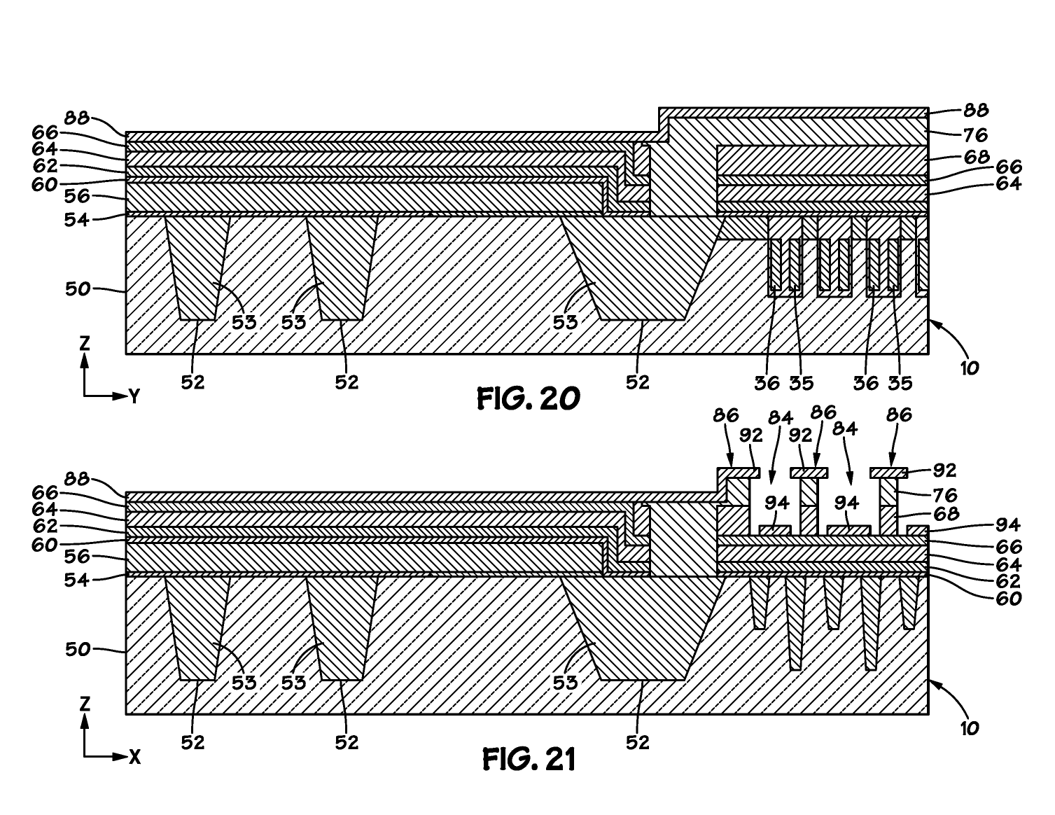

Next, as shown in the front and side views illustrated in FIGS. 20 and 21 respectively, portions of the polysilicon 88 may be removed from the recesses 84, such as by wet stripping or other suitable process. The polysilicon 88 may be removed from the sidewalls of the recesses 84, leaving polysilicon spacers 92 on the rows 86. As shown in FIG. 21, the spacers 92 may slightly overhang the rows 86 and extend over a portion of the recesses 84. In some embodiments, a portion 94 of the polysilicon 88 may remain in bottom of the recesses 84 and protect the bottom portion of the recesses 84 during subsequent processing.

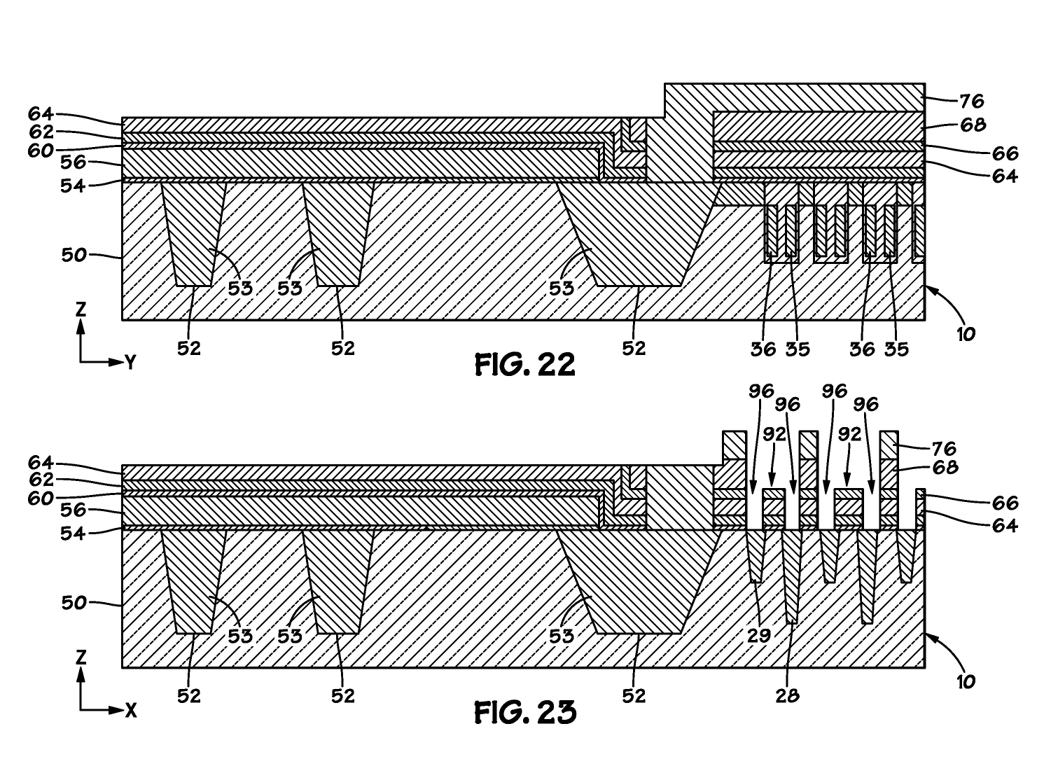

As depicted in the front and side views illustrated in FIGS. 22 and 23 respectively, the array 10 may be etched, such as by dry etching, to form trenches 96 and rows 98. The etch may remove the polysilicon 88 and etch the exposed regions of the recesses 84 not protected by the polysilicon spacers 92 and the polysilicon portion 94 to form trenches 96 and rows 98. The etch may remove all of the materials of the stack 65 on the array 10, exposing the dielectrics 28 and 29. For example, the etch may remove the third conductive material 66, the second conductive material 64, the first conductive material 62, and the polysilicon 60 formed on the array 10 and exposed to the etch. As explained below, the etch depicted in FIGS. 22 and 23 may provide for separation between cells and corresponding access lines formed on the array 10 and coupled to the transistors 40 of the fins 18.

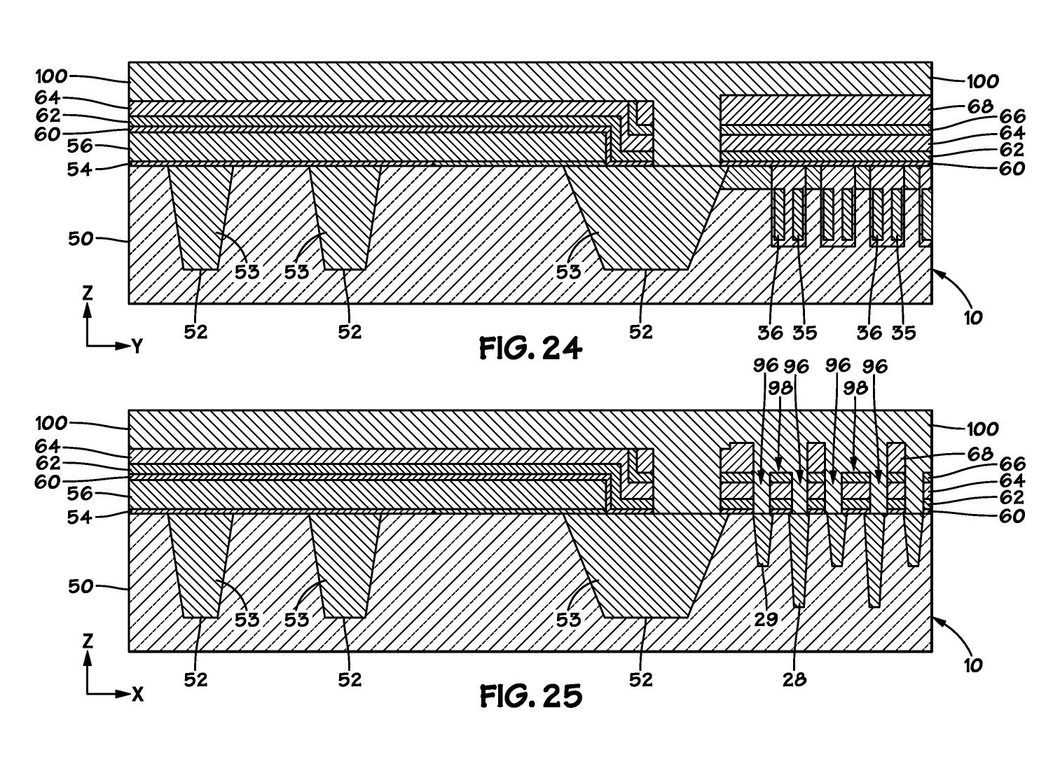

Next, a dielectric 100 may be formed on the periphery 50 and array 10, as illustrated in the front and side views depicted in FIGS. 24 and 25 respectively. The dielectric 100 may be deposited and planarized to form a substantially planar surface on the periphery 50 and array 10. In some embodiments, the dielectric 100 may be TEOS may have a thickness of about 100 Å or greater than or less than 100 Å.

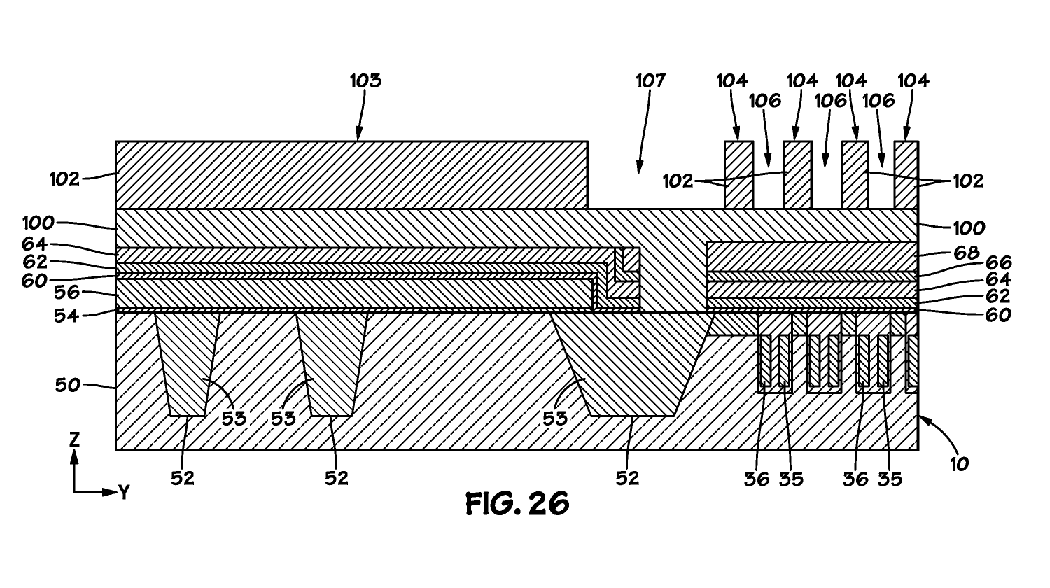

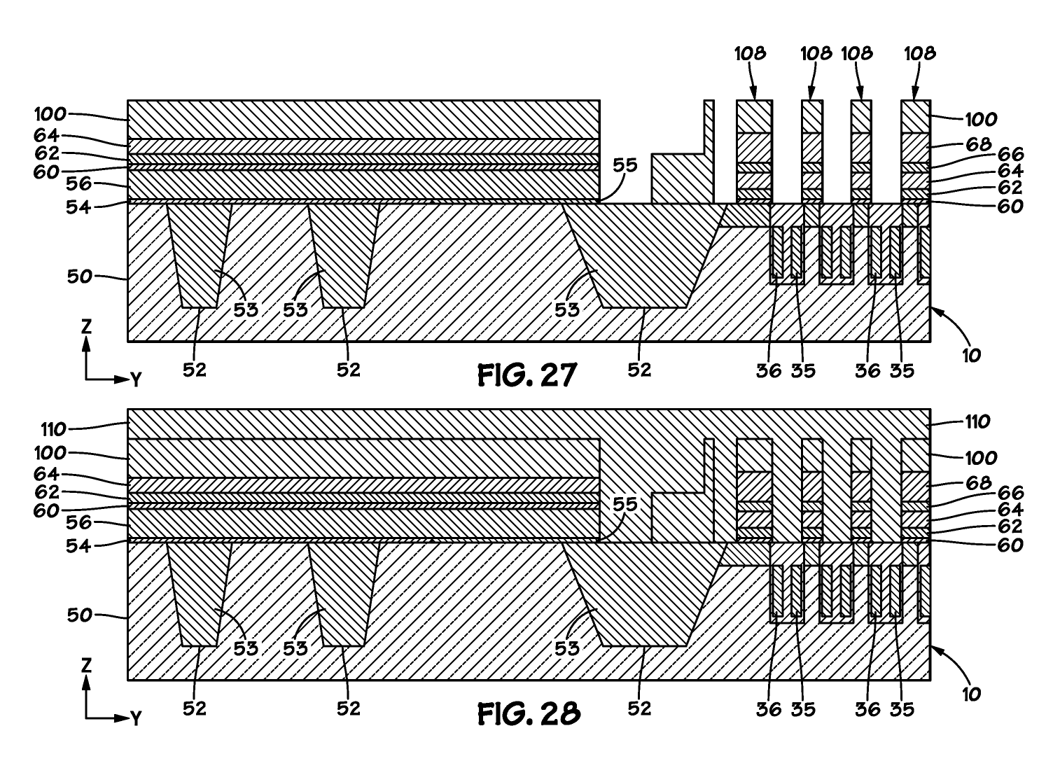

Next, as shown in FIG. 26, a mask 102 (e.g., a photoresist mask) may be patterned on the periphery 50 and the array 10. The mask 102 may include a first portion 103 that covers a portion of or substantially all of the periphery 50. Additionally, the mask 102 may include rows 104 formed generally parallel to the fins 18, perpendicular to the trenches 96, and defining exposed regions 106 between the rows 104. Additionally, the mask 102 may define exposed region 107 in the between the periphery 50 and the array 10. As shown in FIG. 27, the exposed regions 106 may be etched to form protrusions 108 extending from the array 10. Each protrusion 108 may be formed from a stack that includes the polysilicon 60, the first conductive material 62, the second conductive material 64, the third conductive material 66, and the dielectric 100. Each protrusion 108 may form a connection to the fourth conductive material 68, i.e., a conductive plate, and thus connect to a cell and/or access line coupled to the transistors 40 of the fins 18. Additionally, the etch may leave a portion of the dielectric 100 between the array 10 and the periphery 50.

Next, as illustrated in FIG. 28, another dielectric 110 may be formed on the periphery 50 and array 10. The dielectric 110 may be deposited and planarized to form a substantially planar surface on the periphery 50 and array 10. In some embodiments, the dielectric 100 may be TEOS and may have a thickness of about 20 nanometers, about 30 nanometers, less than 20 nanometers, less than 30 nanometers, or greater than 30 nanometers.

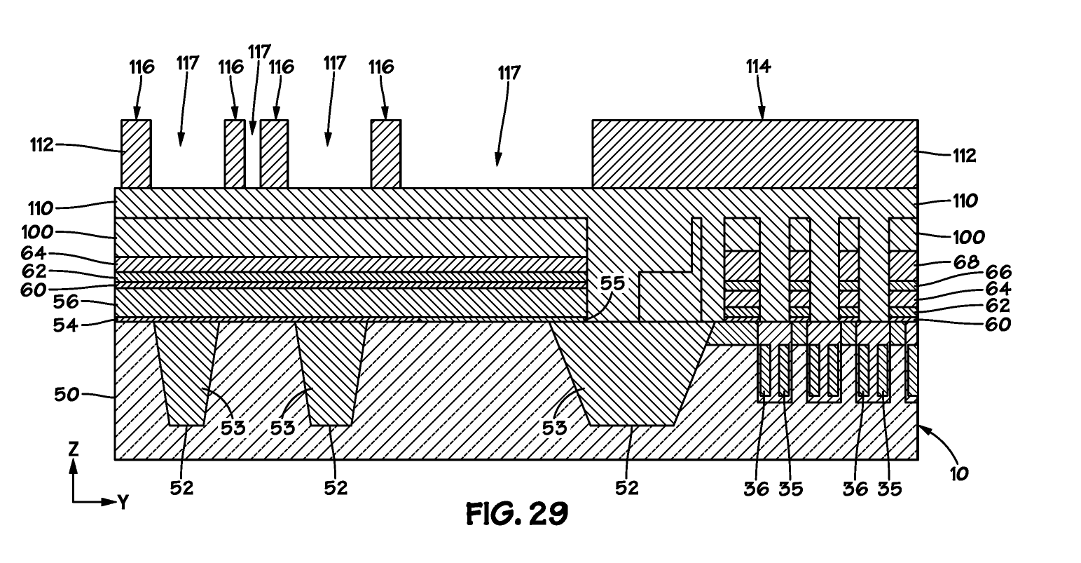

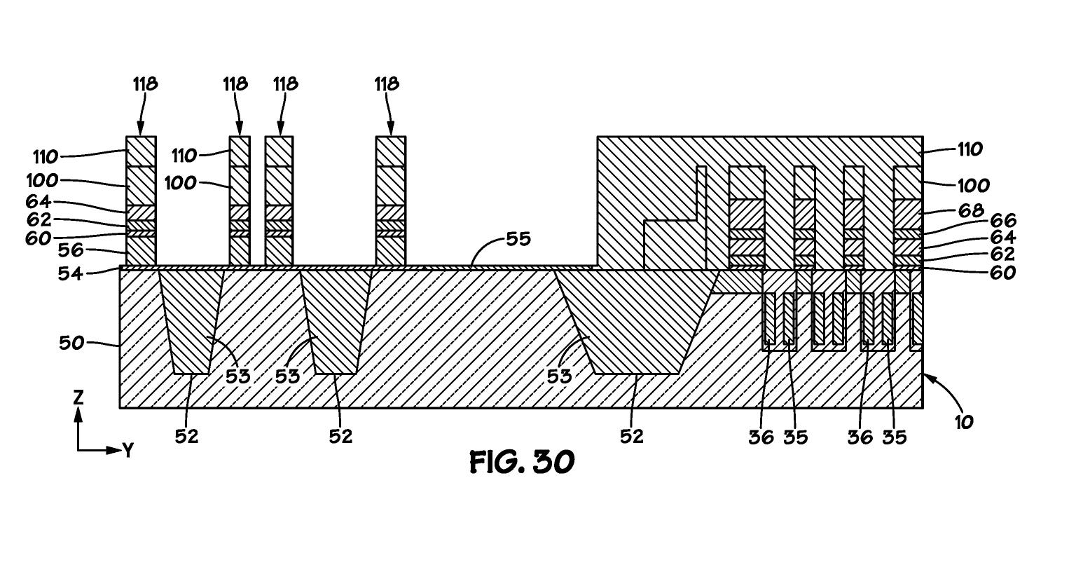

A shown in FIG. 29, a mask 112 may be formed on the periphery 50 and on the array 10. The mask 112 may include a portion 114 formed on a portion of or substantially all of the array 10. The mask 112 may include rows 116 formed on the periphery 50 and defining exposed regions 117. Next, as illustrated in FIG. 30, the periphery 50 may be etched, such as by dry etch, and the mask 112 removed to form rows 118 on the periphery 50. The etching may etch up to the gate oxides 54 and 55 and may remove the materials of the stack on the periphery 50 under the exposed regions 117, such the polysilicon 56, the polysilicon 60, the first conductive material 62, the second conductive material 64, and the dielectrics 100 and 110. The rows 118 may be used to form gates on, and connections to, the periphery 50 during subsequent processing.

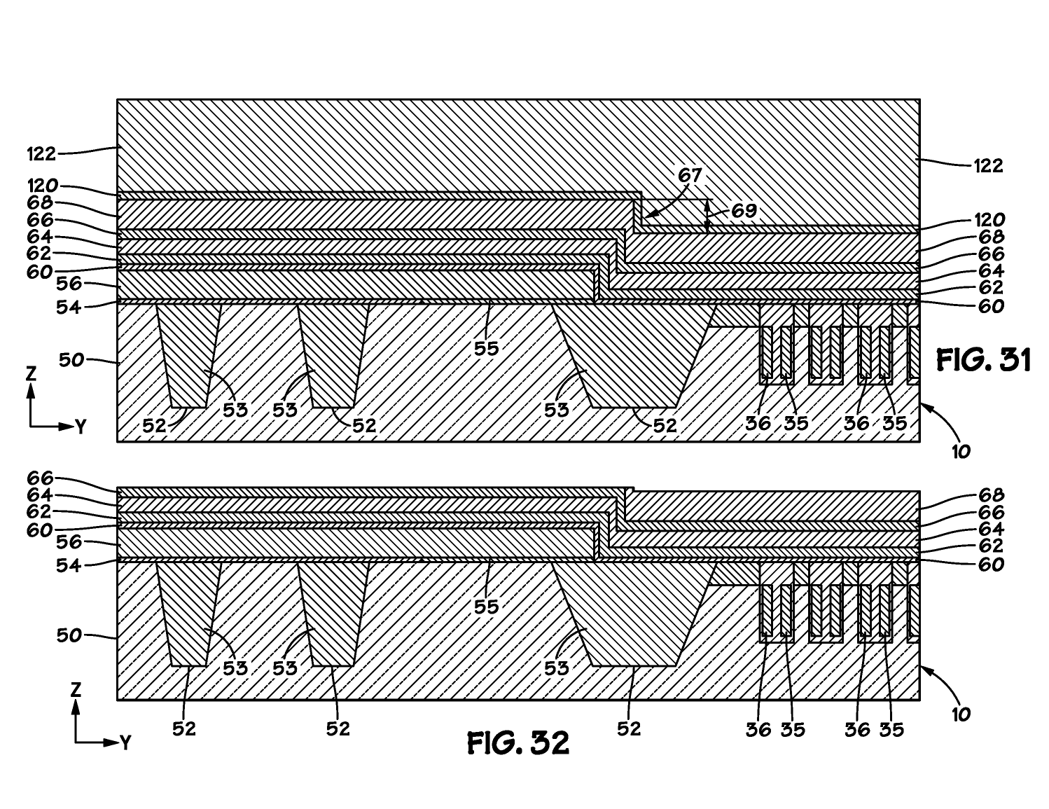

FIGS. 31-49 depict another example of a process for forming conductive components (e.g., conductive plates and access lines) on the array 10 and periphery 50. As compared to the process described above in FIGS. 3-30, the process described below in FIGS. 31-49 may planarize the stacks formed on the periphery 50 and array 10 and eliminate the step earlier in the manufacturing process.

First, as described above in FIGS. 3 and 4, the gate oxides 54 and 55 and the polysilicon 56 may be formed on the periphery 50. In some embodiments, a nitride (e.g., silicon, etc.) may be formed on the array 10. The nitride may protect the gates 35 and 36 from oxidation during formation of the gate oxides 54 and 55. Next, as also shown in FIGS. 5 and 6, the polysilicon 60, the first conductive material 62, the second conductive material 64, the third conductive material 66, and the fourth conductive material 68 may be formed on the periphery 50 and array 10. As also described above, the formation of these materials on the periphery 50 and array 10 may create a step 67 having a step height 69 between the periphery 50 and the array 10. As also mentioned above, the fourth conductive material 68 may form a conductive plate on the array 10 while the portion of the fourth conductive material 68 on the periphery 50 is removed during subsequent processing.

Next as shown in FIG. 31, a silicon nitride liner 120 may be formed on the fourth conductive material 68 on the periphery 50 and array 10. A spin-on dielectric 122 may then be formed on the silicon nitride liner 120. In some embodiments, the silicon nitride liner 120 may have a thickness of about 60 Å or greater than or less than 60 Å, and the spin-on dielectric 122 may have a thickness of about 550 Å or greater than or less than 550 Å. The spin-on dielectric 122 may be formed by low temperature densification or other suitable processes. Next, as shown in FIG. 32, the periphery 50 and array 10 may be etched, removing the spin-on dielectric 122 and silicon nitride 120. The etching may use the third conductive material 66 as stop layer, removing the fourth conductive material 68 from the periphery 50 but leaving the fourth conductive material 68 on the array 10.

As shown in FIG. 32, this process also removes the step 67 between the periphery 50 and array 10, thus eliminating the step height 69. Accordingly, the stacks on the periphery 50 and on the array 10 are at the same height for subsequent processing. As compared to the process depicted in FIGS. 3-30, the process shown in FIGS. 31 and 32 removes the step 67, through planarization of the spin-on dielectric 122, before any photolithography processing, i.e., before any photoresist masks and subsequent etching.

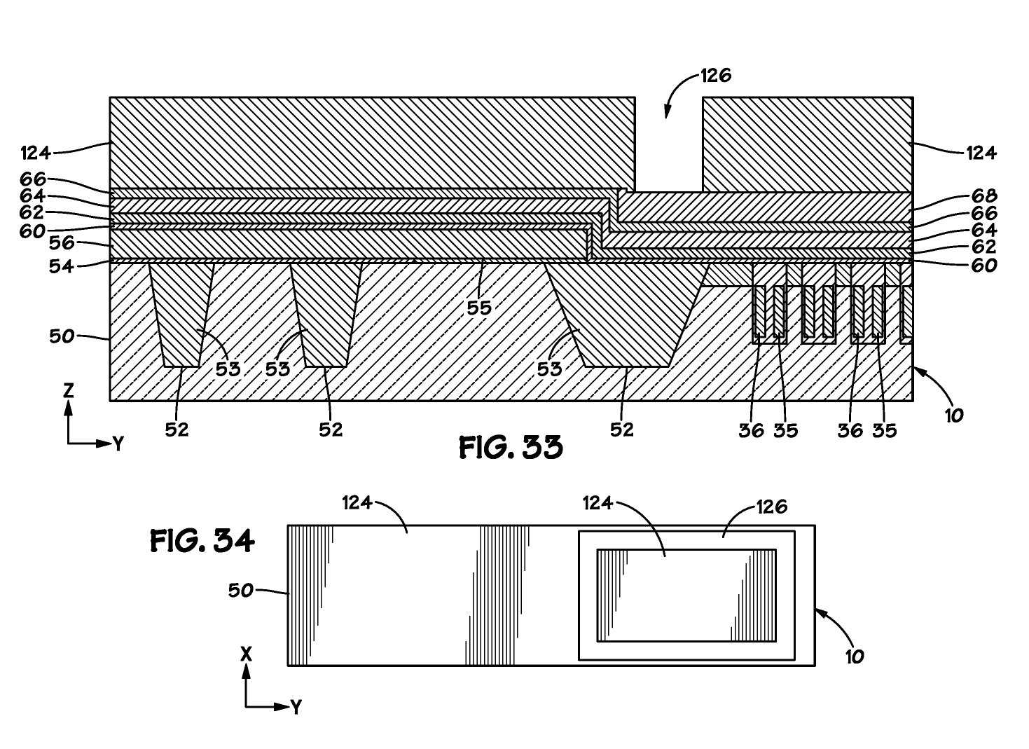

Next, as shown in FIGS. 33 and 34, a mask 124 (e.g., a photoresist mask) may be formed on the periphery 50 and the array 10, such as by suitable photolithographic processes. The mask 124 may define an exposed region 126 around the array 10. FIG. 34 depicts a top view of the periphery 50 and array 10 further illustrating the mask 124 and the exposed region 126. As shown in FIG. 33, the exposed region 126 may form a generally rectangular outline around the array 10, while the periphery 50 and interior of the array 10 are masked by the mask 124.

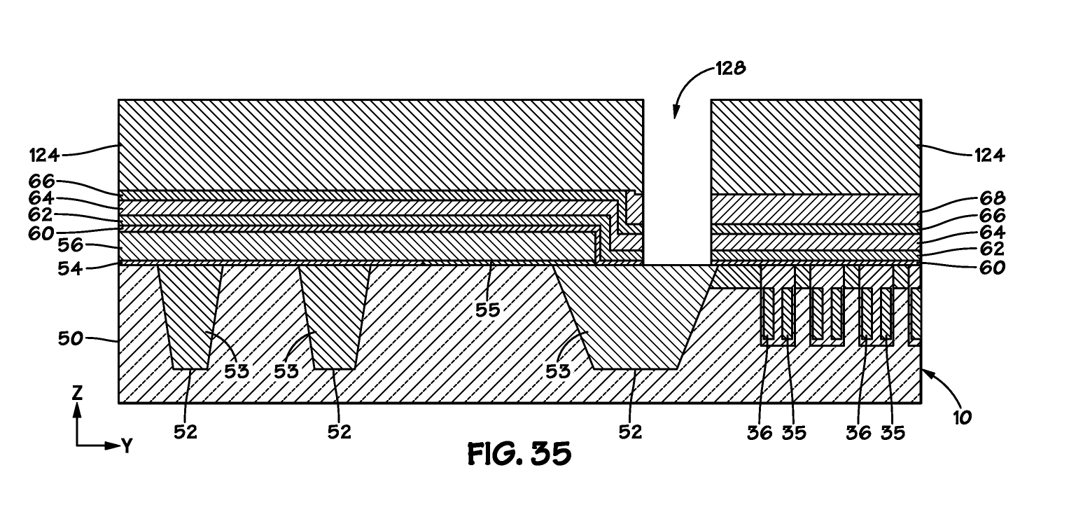

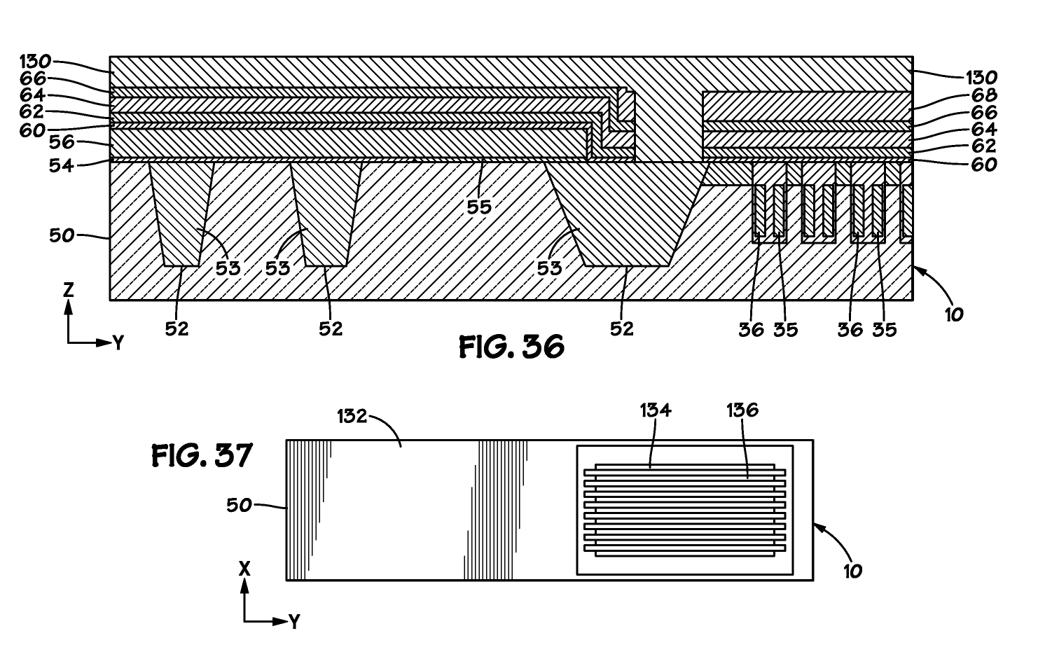

As shown in FIG. 35, the exposed region 126 may be etched, such as by dry etching, to form a band 128 around the array 10. The band 128 forms a generally rectangular outline around the array 10. As shown in FIG. 35, the band 128 separates the stack on the periphery 50 from the stack on the array 10. Next, as illustrated in FIG. 36, the mask 124 may be removed and a dielectric 130 may be formed on the periphery 50 and the array 10, filling the band 128. In some embodiments, the dielectric 130 may be TEOS and may have a thickness of about 500 Å or greater than or less than 500 Å.

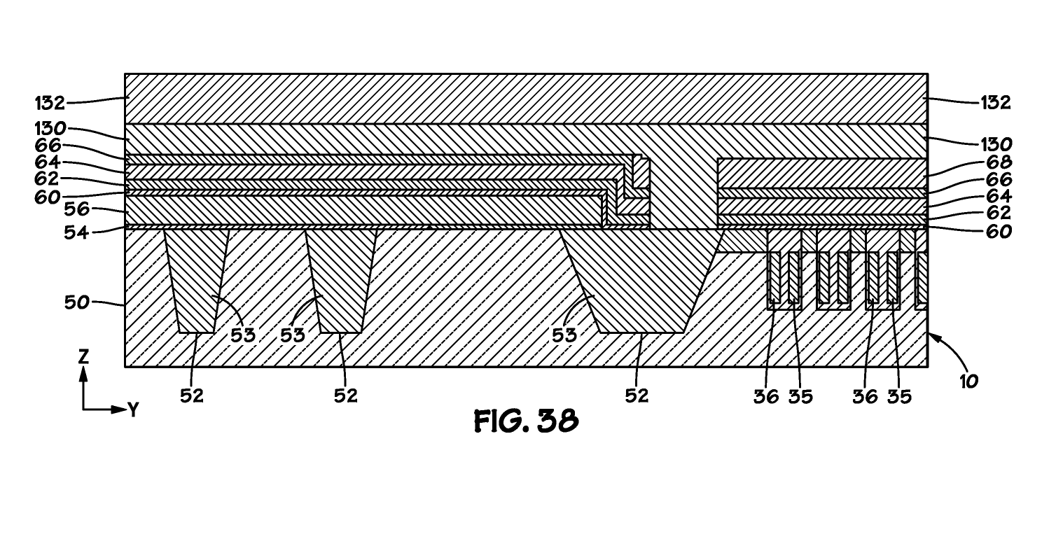

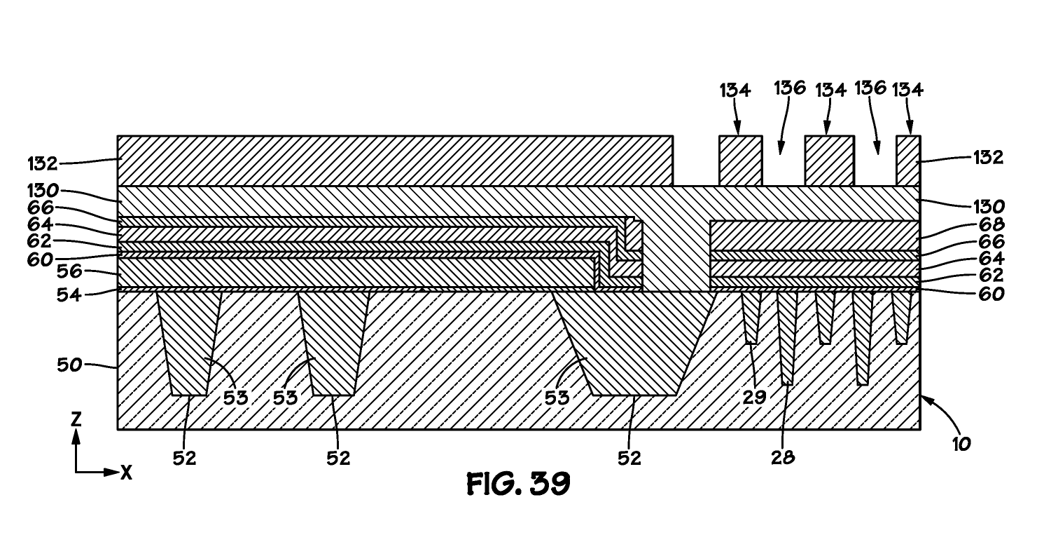

As shown in FIGS. 37-39, a mask 132 may be patterned on the array 10. FIG. 37 is a top view of the periphery 50 and array 10 further illustrating the mask 132. As shown, the mask 132 may be patterned in rows 134 having exposed regions 136 between the rows 134. As shown in FIG. 38, the rows 134 of the mask 132 may be patterned on the array 10 and periphery 50 and may extend over the array 10 and the periphery 50. FIG. 39 is a side view of the periphery 50 and array 10 depicting the mask 132, rows 134, and exposed regions 136. In some embodiments, the rows 134 of the mask 132 may be pitch doubled with respect to the transistors 40.

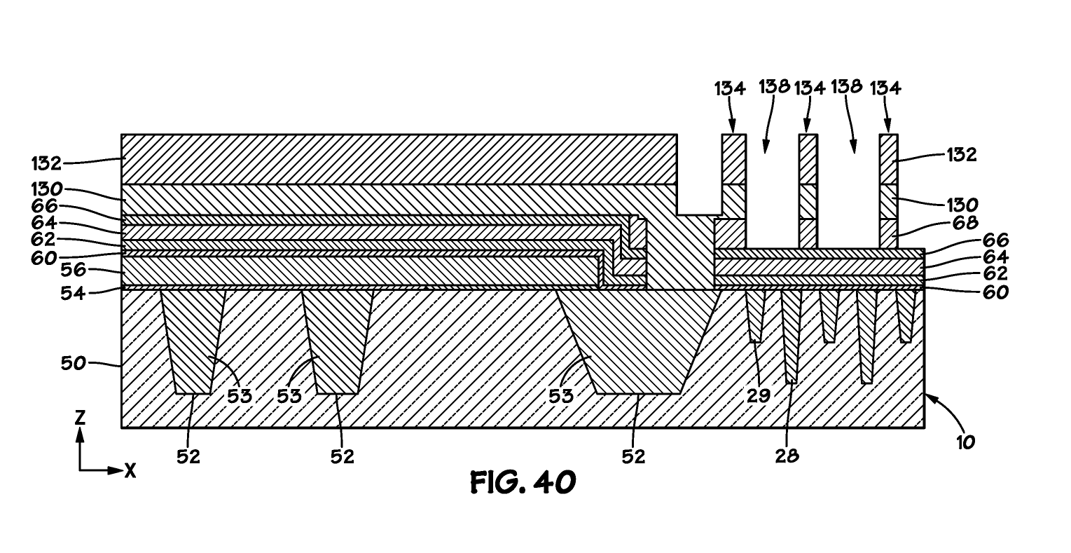

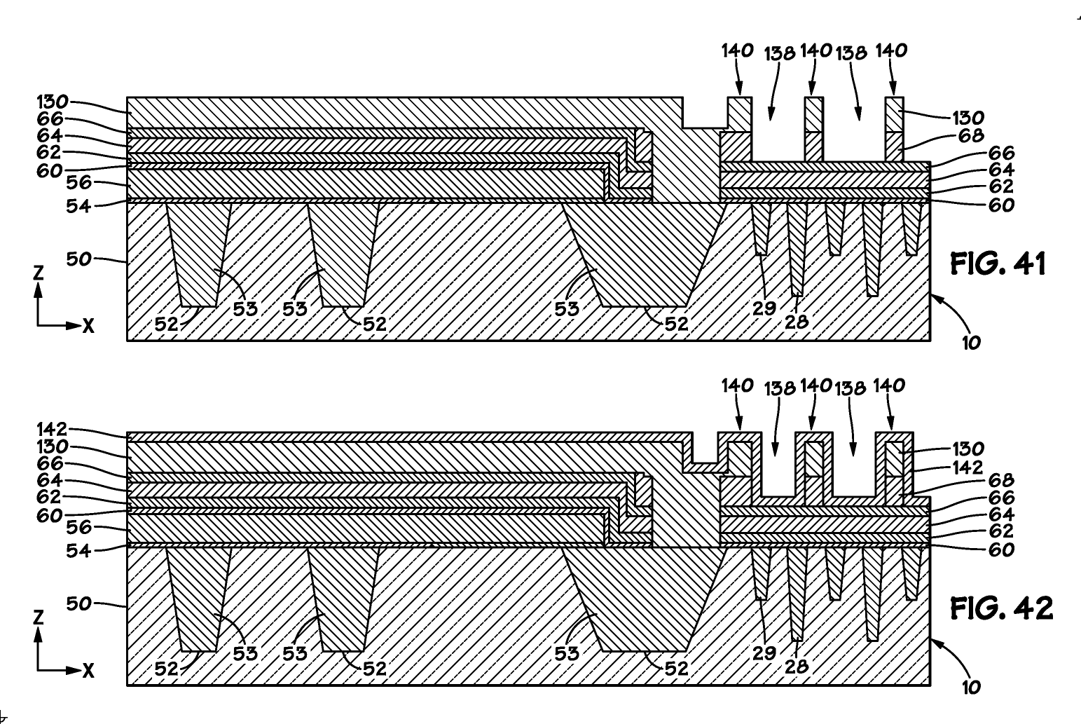

Next, as shown in the side view of FIG. 40, the exposed regions 136 may be etched to form recesses 138 in the array 10 and between the rows 134. In some embodiments, the etch may use the third conductive material 66 as a stop layer, removing the materials formed on the third conductive material 66. For example, the recesses 138 in the array 10 may be etched up to the third conductive material 66, removing the fourth conductive material 68 and the dielectric 130 from the exposed regions 82. Next, as shown in the side view illustrated in FIG. 41, the mask 132 may be removed, such as by carbon dioxide stripping or other suitable process, leaving rows 140 formed from the dielectric 130 and the fourth conductive material 68. As stated above, the rows 140 may be separated by the recesses 138.

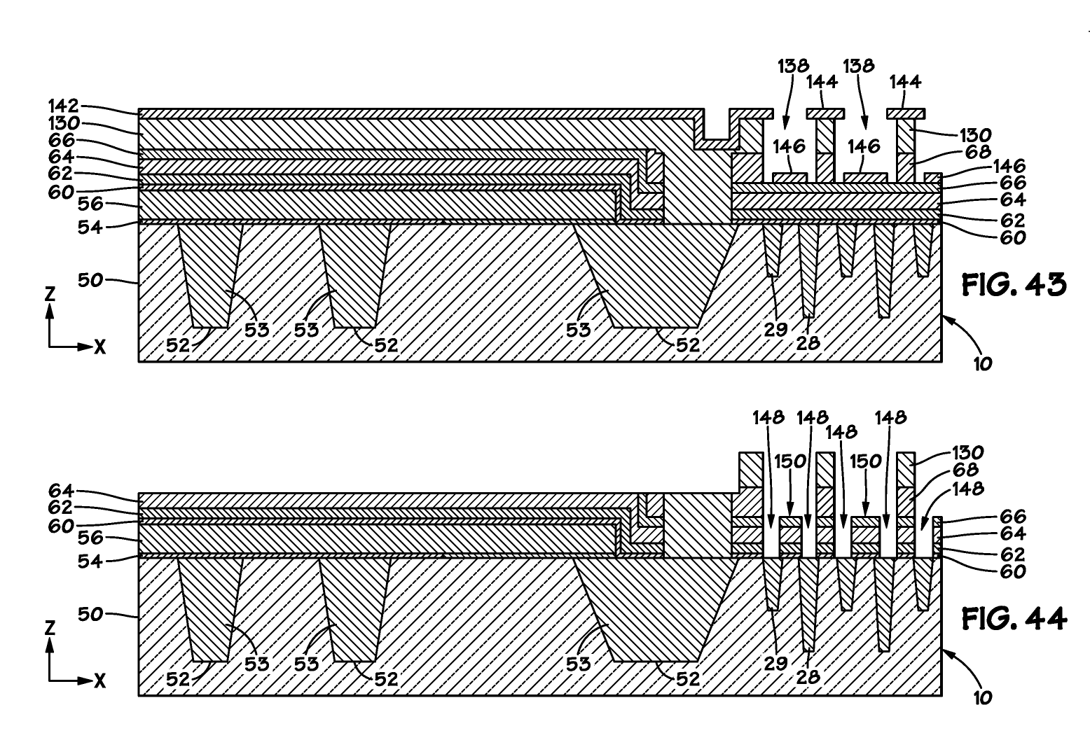

As shown in the side view illustrated in FIG. 42, a polysilicon 142 may be formed on the periphery 50 and the array 10. The polysilicon 142 may be formed on the dielectric 130 on the periphery 50 and the array 10 and on the third conductive layer 66 in the recesses 138. In some embodiments, the polysilicon may have a thickness of about 150 Å or greater than or less than 150 Å. After formation of the polysilicon 142, the periphery 50 and array 10 may be subjected to ion implantation, such as boron difluoride (BF₂) implantation. Next, as depicted in FIG. 43, portions of the polysilicon 142 may be removed from the recesses 138, such as by wet stripping or other suitable process. The polysilicon 142 may be removed from the sidewalls of the recesses 138, leaving polysilicon spacers 144 on the rows 86. As shown in FIG. 42 the spacers 144 may slightly overhang the rows 140 and extend over a portion of the recesses 138. In some embodiments, a portion 146 of the polysilicon 142 may remain in the recesses 138 and protect the bottom portion of the recesses 138 during subsequent processing.

Next, as shown in FIG. 44, the array 10 may be etched, such as by dry etching, to form trenches 148 and rows 150. The etch may remove the polysilicon 142 and etch the exposed regions of the recesses 138 not protected by the polysilicon spacers 144 and the polysilicon portion 146. The etch may remove all the materials of the stack 65 on the array 10, exposing the dielectrics 28 and 29. For example, the etch may remove the third conductive material 66, the second conductive material 64, the first conductive material 62, and the polysilicon 60 formed on the array 10 and exposed to the etch. As explained below, the etch depicted in FIG. 44 may provide for separation between cells and corresponding access lines formed on the array 10 and coupled to the transistors 40 of the fins 18.

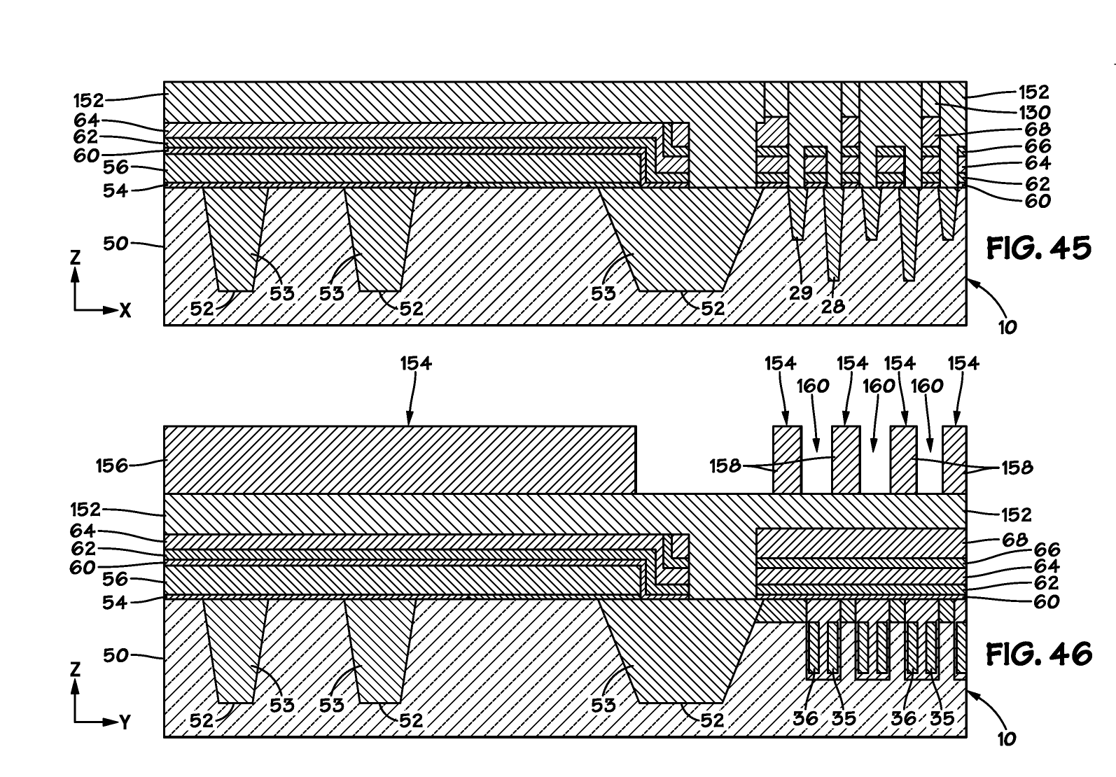

Next, a dielectric 152 may be formed on the periphery 50 and array 10, as shown in FIG. 45. The dielectric 152 may be deposited and planarized to form a substantially planar surface on the periphery 50 and array 10. In some embodiments, the dielectric 152 may be TEOS and may have a thickness of about 20 nanometers, about 30 nanometers, less than 20 nanometers, less than 30 nanometers, or greater than 30 nanometers.

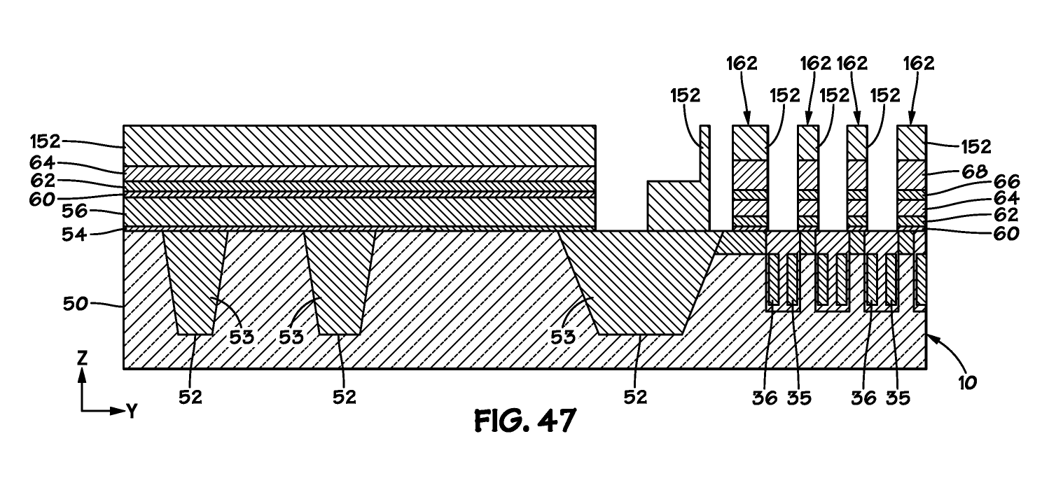

Turning again to a front view of the array 10 and periphery 50 as depicted in FIG. 46, a mask 154 (e.g., a photoresist mask) may be formed on the periphery 50 and the array 10. The mask 154 may include a first portion 156 that covers a portion of or substantially all of the periphery 50. Additionally, the mask may include rows 158 formed on the array 10 generally parallel to the fins 18, perpendicular to the trenches 148, and defining exposed regions 160 between the rows 154. Next, as shown in FIG. 47, the exposed regions 160 may be etched to form protrusions 162 extending from the array 10. Each protrusion 162 may be formed from the stack that includes the polysilicon 60, the first conductive material 62, the second conductive material 64, the third conductive material 66, and the dielectrics 152 and 162. Each protrusion 162 may connect to the fourth conductive material 68, i.e., a conductive plate, and thus connect to a cell and/or access line coupled to the transistors 40 of the fins 18. After the etch, the mask 154 may be removed by any suitable process and leave a portion of the dielectric 152 between the array 10 and the periphery 50.

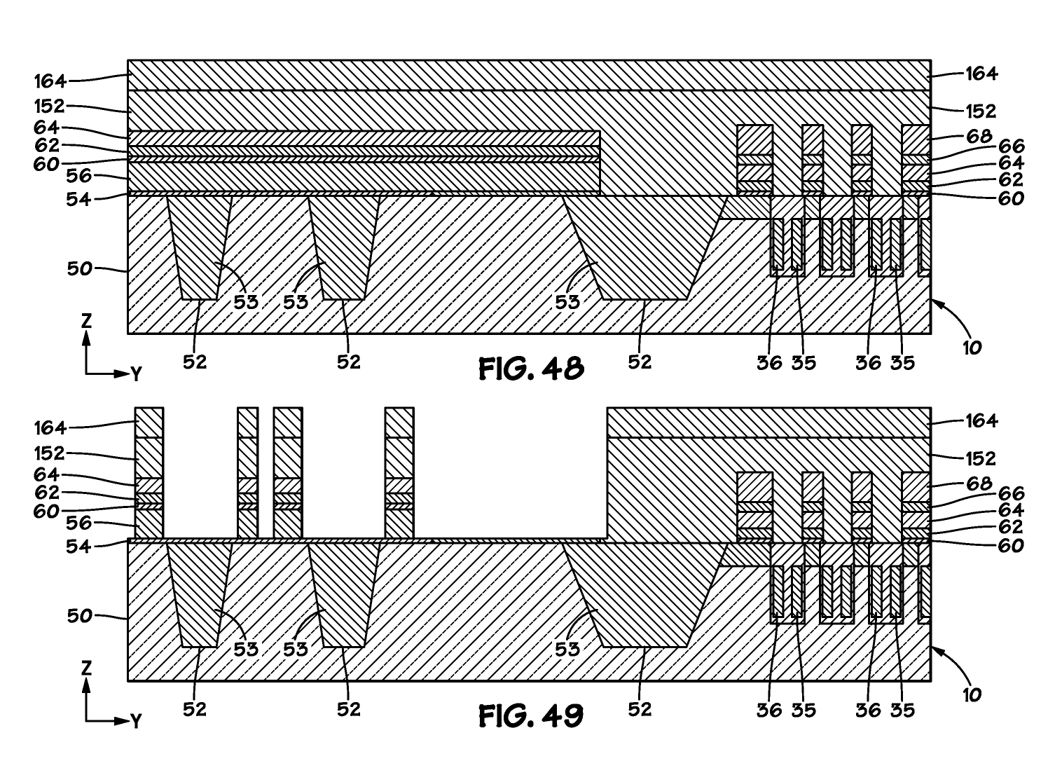

Next, as shown in FIG. 48, another dielectric 164 may be formed on the periphery 50 and array 10. The dielectric 164 may be deposited and planarized to form a substantially planar surface on the periphery 50 and array 10. In some embodiments, the dielectric 100 may be TEOS and may have a thickness of about 20 nanometers, about 30 nanometers, less than 20 nanometers, less than 30 nanometers, or greater than 30 nanometers. Next, as shown FIG. 49 and as described above in the process illustrated in FIGS. 29 and 30, the rows 164 may patterned and etched on the periphery 50, such as through a mask and subsequent etching. The etch may remove the materials of the stack on the periphery 50 up to the gate oxides 54 and 55, such the polysilicon 56, the polysilicon 60, the first conductive material 62, the second conductive material 64, and the dielectrics 164 and 152. The rows 164 may form gates on, and connections to, the periphery 50 during subsequent processing.

While the invention may be susceptible to various modifications and alternative forms, specific embodiments have been shown by way of example in the drawings and will be described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method, comprising:
simultaneously forming a first stack of conductive materials on a memory array and a second stack of the conductive materials on a periphery of the memory array, wherein the first stack and the second stack are formed with a stack height differential between the first stack and the second stack
removing one or more of the conductive materials from the second stack to eliminate the stack height differential; and
forming a plurality of connections on the memory array from the conductive materials of the first stack to a plurality of gates or transistors of the memory array.

2. The method of claim 1, comprising forming a second plurality of connections on the periphery from the second stack.

3. The method of claim 2, forming a second plurality of connections on the periphery from the second stack comprises patterning a mask defining exposed regions on the second stack and etching the exposed regions.

4. The method of claim 1, wherein the conductive materials comprise tungsten.

5. The method of claim 4, wherein the plurality of connections on the array comprise a conductive tungsten plate.

6. The method of claim 1, wherein the conductive materials comprise titanium nitride, tungsten nitride, tungsten silicide, tungsten, or a combination thereof.

7. The method of claim 1, comprising forming a polysilicon on the memory array and the periphery.

8. The method of claim 7, wherein forming the first stack of conductive materials on a memory array and the second stack the conductive materials on a periphery comprises forming the conductive materials on the polysilicon.

9. The method of claim 1, wherein forming a plurality of connections on the array from the first stack comprises patterning a mask defining exposed regions on the first stack and etching the exposed regions.

10. The method of claim 9, wherein etching the exposed regions comprise removing the conductive materials of the first stack from the exposed regions.

11. The method of claim 1, comprising depositing and planarizing a dielectric on the periphery and the array.

12. A method, comprising:
forming a first conductive material on a memory array and a periphery of the memory array, wherein the first conductive material is formed a first height to the periphery and on a second height on the stack, wherein the first height and second height define a height differential;
forming a dielectric on the first conductive material; and
etching the periphery and memory array to remove the height differential, wherein the etching removes the first conductive material on the periphery.

13. The method of claim 12, wherein the dielectric comprises a spin-on dielectric.

14. The method of claim 12, comprising forming a silicon nitride liner on the memory array and the periphery.

15. The method of claim 12, wherein the first conductive material comprises tungsten.

16. The method of claim 12, comprising forming connections to the memory array from the first conductive material.

17. The method of claim 16, wherein forming connections to the memory array comprises patterning and etching a plurality of protrusions on the memory array.

18. The method of claim 12, comprising patterning a mask on the memory array and periphery to define an exposed region on the memory array.

19. The method of claim 18, comprising etching the exposed region to form a band around the memory array.

20. A method, comprising:
forming a first conductive material on a memory array and a periphery of the memory array;
forming a second conductive material on the first conductive material;
removing the second conductive material to form a stack on the periphery, wherein the height of the stack is defined by the first conductive material; and
forming a plurality of connections to the periphery from the stack.

21. The method of claim 20, wherein the first conductive material comprises titanium nitride.

22. The method of claim 20, wherein the second conductive material comprises tungsten.

23. The method of claim 20, wherein removing the second conductive material comprises etching the second conductive material on the periphery and not etching the second conductive material on the memory array.

24. The method of claim 23, comprising depositing a dielectric on the second conductive material before removing the second conductive material.

25. The method of claim 24, comprising removing the second conductive material before any photolithography on the stack.

26. A device, comprising:
a memory array comprising a plurality of fin field effect transistors (finFETS);
a periphery adjacent the memory array;
a first stack of conductive materials formed on the memory array;
a second stack of the conductive materials formed on the periphery, wherein the first stack and the second stack are formed with a stack height differential between the first stack and the second stack.
